(19) United States
(12) Patent Application Publication
(10) Pub. No.: US 2011/0075376 A1
(43) Pub. Date: Mar. 31, 2011

(54) Module substrate radiating heat from electronic component by intermediate heat transfer film and a method for manufacturing the same

(75) Inventor: Masanori Itoh, Tokyo (JP)

(73) Assignee: OKI ELECTRIC INDUSTRY CO., LTD., Tokyo (JP)

(21) Appl. No.: 12/923,577

(22) Filed: Sep. 28, 2010

(30) Foreign Application Priority Data
Sep. 29, 2009 (JP) 2009-223783

(51) Int. Cl. H05K 7/20; H01L 21/50

(52) U.S. Cl. 361/707; 438/118; 257/E21.499

(57) ABSTRACT

A module substrate having a heat-generative electronic component mounted thereon includes first and second dielectric substrates and an intermediate heat transfer film. The heat-generative electronic component is flip-chip bonded on a wiring layer formed on the main surface of the first dielectric substrate through a solder bump. The second dielectric substrate is attached to the upper surface of the electronic component through an insulating layer. The intermediate heat transfer film for transferring heat generated by the electronic component to the second dielectric substrate is attached between the insulating layer and the second dielectric substrate so as to make the intermediate heat transfer film in close contact with the lower surface of the second dielectric substrate, thereby suppressing the temperature of the heat-generative electronic component in operation from increasing.

### BACKGROUND OF THE INVENTION

1. Field of the Invention

The present invention generally relates to a microelectronic module assembly, and more particularly to a module substrate having an electronic component, such as a heat-generative electronic component, mounted thereon. The present invention also relates to a method for manufacturing such a microelectronic module assembly.

2. Description of the Background Art

A high frequency module is known which has high frequency components, such as a high frequency power amplifier component, a high frequency filter component and a high frequency branching filter component, integrally mounted by flip-chip bonding on a dielectric substrate, as disclosed in Japanese patent laid-open publication Nos. 2006-203652, 2003-051733 and 2003-304048, for example. In addition, a power amplifier module is known in which a power amplifier component for use in communication in a microwave bandwidth is mounted on a dielectric substrate, as disclosed in Japanese patent laid-open publication No. 2005-191435, for example.

Such high frequency modules and power amplifier modules are actively used for mobile communication devices, such as cellular phones. Mobile communication devices are strongly required to be downsized. When downsizing, the devices are also strongly required to efficiently radiate to the exterior heat generated by heat-generative electronic components, such as a high frequency power amplifier component.

In the case of forming a module substrate, in order to provide effective electric insulation and anti-moisture or dust sealing against heat-generative electronic components mounted on a dielectric substrate, a measure is taken to cover those components with a resin, such as an epoxy resin or a phenol resin. Since the resin and the dielectric substrate are low in heat conductivity, it can be said that the heat-generative electronic components have the periphery thereof covered with a material having poor heat conductivity. Consequently, the temperature of the heat-generative electronic components is increased in operation, thus deteriorating the operating characteristics thereof or causing malfunction in some cases.

Therefore, with conventional module substrates having heat-generative electronic components mounted by flip-chip bonding on a dielectric substrate, a variety of mechanisms are contrived such as to efficiently radiate heat from the lower surface of the heat-generative electronic components to the exterior. Regarding another heat from the opposite surface, i.e. the upper surface, to the lower surface of the heat-generative electronic components of the components, however, effective mechanisms have not been taken for efficiently radiating this heat to the exterior. It is thus limitative to effectively prevent the temperature of the heat-generative electronic components due to heat generated by themselves from increasing.

### SUMMARY OF THE INVENTION

The inventor of the present patent application has dedicated himself to studying mechanisms for efficiently dissipating or radiating heat from the upper surface of a heat-generative electronic component. As a result, a simulation the inventor conducted confirms that the problems are solved by the structure in which a material having high heat conductivity is positioned adjacent to the upper surface of a heat-generative electronic component with an insulating layer intervening, thus effectively preventing the temperature of the heat-generative electronic component from increasing.

It is thus an object of the present invention to provide a microelectronic module assembly having a heat-generative electronic component mounted thereon to be capable of efficiently radiating heat generated by the heat-generative electronic component to the exterior. It is also an object of the invention to provide a method for manufacturing such a microelectronic module assembly.

In accordance with the present invention, a microelectronic module assembly has a heat-generative electronic component which is flip-chip bonded through a solder bump on a wiring layer formed on a main surface of a first dielectric substrate. In the module assembly, a second dielectric substrate is attached on an upper surface opposite to a lower surface of the heat-generative electronic component facing the first dielectric substrate through an insulating layer.

The module assembly having a heat-generative electronic component mounted thereon in accordance with the invention is configured by sandwiching the heat-generative electronic component between the first and second dielectric substrates, and further has the following configuration.

An intermediate heat transfer film for transferring heat generated by the heat-generative electronic component to the second dielectric substrate is attached between the insulating layer formed on the upper surface of the heat-generative electronic component and the second dielectric substrate so as to make the intermediate heat transfer film in close contact with a lower surface of the second dielectric substrate adjacent to the heat-generative electronic component.

The module assembly in accordance with the invention can be manufactured by a method including the following steps.

The method for manufacturing the module assembly in accordance with the invention may include a flip-chip bonding step, an intermediate dielectric substrate attaching step, and a second dielectric substrate attaching step.

In the flip-chip bonding step, a first dielectric substrate having a wiring layer formed on its main surface is prepared, and an electrical connection of the heat-generative electronic component to the wiring layer is formed through a solder bump.

In the intermediate dielectric substrate attaching step, an intermediate dielectric substrate provided with a hole for surrounding the heat-generative electronic component is prepared, a dielectric adhesive agent is applied to the main surface of the first dielectric substrate and an upper surface of the heat-generative electronic component, and the intermediate dielectric substrate is attached to the main surface of the first dielectric substrate through the dielectric adhesive agent so as to fit the heat-generative electronic component into the hole. The dielectric adhesive agent is solidified to form an insulating layer.

In the second dielectric substrate attaching step, a second dielectric substrate provided with an intermediate heat transfer film is prepared, and the second dielectric substrate is attached so as to position the intermediate heat transfer film above the upper surface of the heat-generative electronic component through the dielectric adhesive agent and so as to bring a portion not provided with the intermediate heat transfer film on a lower surface of the second dielectric substrate into close contact with an upper surface of the intermediate dielectric substrate.

In accordance with an aspect of the invention, an alternative configuration of module assembly may be configured by further adding the following mechanism to the above-described module assembly.

In the alternative configuration of module assembly, on the top heat radiation film formed on the upper surface opposite to the lower surface of the second dielectric substrate has a structure including a through hole for connecting the intermediate heat transfer film with the top heat radiation film.

The alternative configuration of module assembly in accordance with the invention can be manufactured by a method including the following steps.

The method for manufacturing the alternative configuration of module assembly in accordance with the invention includes, in addition to the flip-chip bonding step, intermediate dielectric substrate attaching step and second dielectric substrate attaching step described above, a through hole forming step and a top heat radiation film forming step following the second dielectric substrate attaching step.

In the through hole forming step, a through hole is formed in the second dielectric substrate.

In the top heat radiation film forming step, a top heat radiation film is formed on the upper surface of the second dielectric substrate provided with the through hole opposite to the heat-generative electronic component.

According to the prevent invention, in the module assembly, the intermediate heat transfer film is positioned between the insulating layer formed on the upper surface of the heat-generative electronic component and the second dielectric substrate so as to make the intermediate heat transfer film in close contact with a lower surface of the second dielectric substrate. By the intermediate heat transfer film thus dispose, heat emanated from the upper surface of the heat-generative electronic component can be efficiently radiated to the exterior. Therefore, by such a heat radiation mechanism provided on the upper surface of the heat-generative electronic component, the temperature of the operating heat-generative electronic component can more effectively controlled from increasing than a conventional module substrate.

Furthermore, according to the prevent invention, in the alternative configuration of module assembly, the structure is provided which interconnects the top heat radiation film formed on the upper surface of the second dielectric substrate and the intermediate heat transfer film with each other by the through hole. By the structure including the through hole, heat reaching the intermediate heat transfer film is efficiently transferred through the through hole to the top heat radiation film formed on the upper surface of the second dielectric substrate. Therefore, the alternative configuration of module assembly in accordance with the invention can more efficiently radiate heat emanated from the upper surface of the heat-generative electronic component to the exterior.

### BRIEF DESCRIPTION OF THE DRAWINGS

The objects and features of the present invention will become more apparent from consideration of the following detailed description taken in conjunction with the accompanying drawings in which:

FIGS. 1A, 1B and 1C are schematic cross sectional views cut along a plane perpendicular to a main surface of a conventional dielectric substrate on which a heat-generative electronic component is mounted;

FIGS. 2A, 2B and 2C are schematic plan views as viewed in a direction perpendicular to the main surface of the conventional dielectric substrate shown in FIGS. 1A, 1B and 1C, respectively;

FIG. 3A is a top plan view showing a conventional module substrate to be simulated for use in understanding conditions set for the simulation;

FIG. 3B is a cross sectional view showing the module substrate cut along line IIIB-IIIB in FIG. 3A;

FIG. 3C shows the shape and position of the heat-generative electronic component shown in FIG. 3B;

FIG. 4 shows how the surface temperature of the heat-generative electronic component is distributed, obtained from the simulation made on the conventional module substrate;

FIGS. 5A, 5B and 5C are cross sectional views cut along a plane perpendicular to a main surface of a dielectric substrate on which a heat-generative electronic component is mounted in accordance with an illustrative embodiment of the present invention;

FIGS. 6A, 6B and 6C are plan views as viewed in a direction perpendicular to the main surface of the dielectric substrate shown in FIGS. 5A, 5B and 5C, respectively;

FIG. 7A is a top plan view showing a module substrate to be simulated for use in understanding conditions set for the simulation in accordance with the illustrative embodiment;

FIG. 7B is a cross sectional view showing the module substrate cut along line VIIB-VIIB in FIG. 7A;

FIG. 7C shows the shape and position of an intermediate heat radiation film;

FIG. 8 shows how the surface temperature of the heat-generative electronic component is distributed, obtained from the simulation made on the illustrative embodiment shown in FIGS. 7A, 7B and 7C;

FIGS. 9A, 9B and 9C are cross sectional views cut along a plane perpendicular to a main surface of a dielectric substrate on which a heat-generative electronic component is mounted in accordance with an alternative embodiment of the present invention;

FIGS. 10A, 10B and 10C are plan views as viewed in a direction perpendicular to the main surface of the dielectric substrate shown in FIGS. 9A, 9B and 9C, respectively;

FIG. 11A is a virtual plan view showing a module substrate to be simulated for use in understanding conditions set for the simulation in the alternative embodiment;

FIG. 11B is a cross sectional view showing the module substrate cut along line XIB-XIB in FIG. 11A; and

FIG. 12 shows a surface temperature distribution of the heat-generative electronic component obtained from the simulation made on the alternative embodiment shown in FIG. 9A to 10C.

### DESCRIPTION OF THE PREFERRED EMBODIMENTS

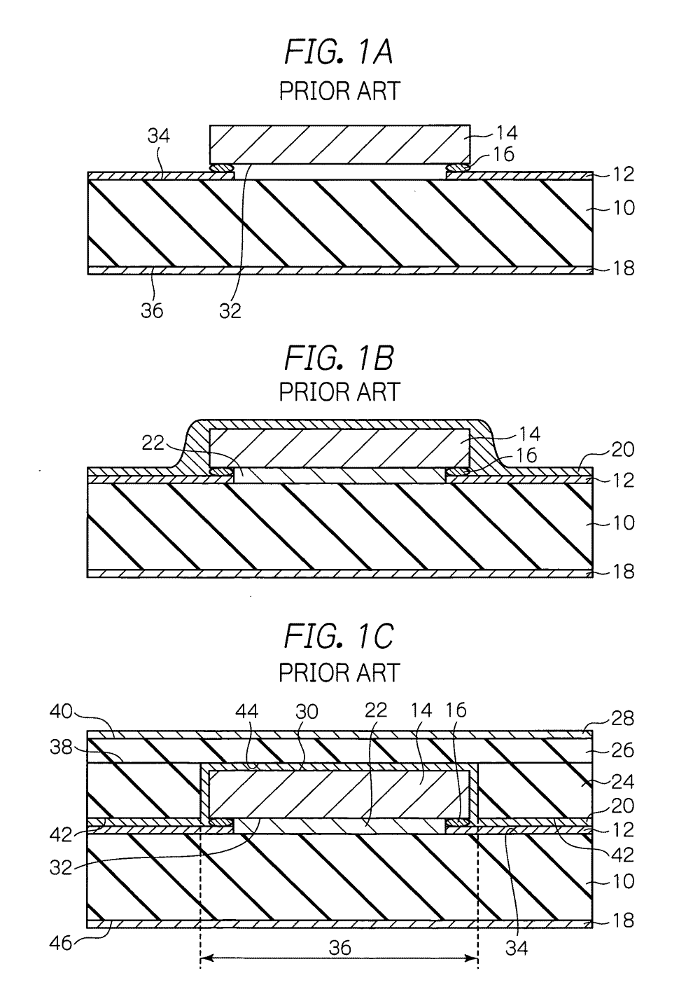

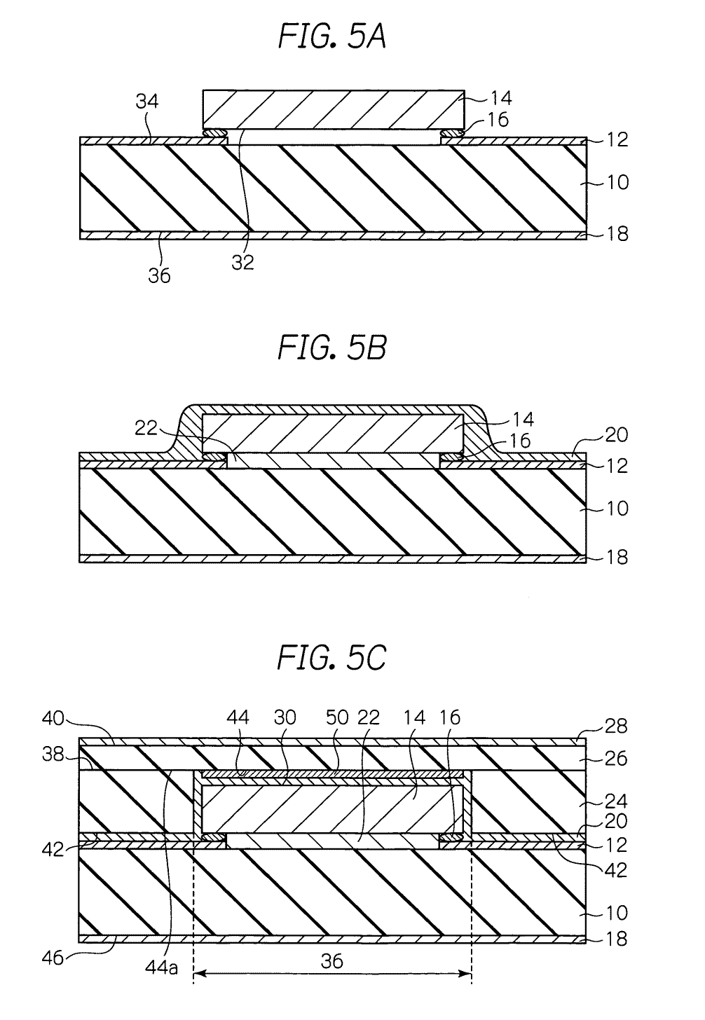

In order to have the invention better understood, reference will first be made to FIGS. 1A to 4 to describe the configuration and thermal characteristics of a typical, conventional module substrate having a heat-generative electronic component mounted thereon, such as a high frequency module or a power amplifier module, to specifically clarify problems to be solved by the present invention. Secondly, illustrative embodiments of the present invention will be described with reference to FIGS. 5A to 12, which merely conceptually show the illustrative embodiments to the extent of understanding the basic configuration and characteristics of a module substrate in accordance with the present invention. Preferred embodiments in accordance with the present invention will be described with materials, numerical conditions or the like of components or elements being just exemplified. Therefore, the present invention is not understood as restrictive to the specific details of the illustrative embodiments. In the figures, like components or elements are designated with the same reference numerals and repetitive descriptions thereon may be refrained from.

With reference first to FIGS. 1A to 4, description will be made on the configuration of a typical, conventional module substrate having a heat-generative electronic component mounted thereon, such as a high frequency module or a power amplifier module, and on the radiation characteristics of heat generated by the heat-generative electronic component. In the context, the term “module substrate” may be understood simply as a substrate per se for use in mounting a microelectronic module as well as more broadly as a module unit having, and hence including, a micro electronic component, such as a heat-generative component, mounted as a modular on a substrate, such as a dielectric substrate.

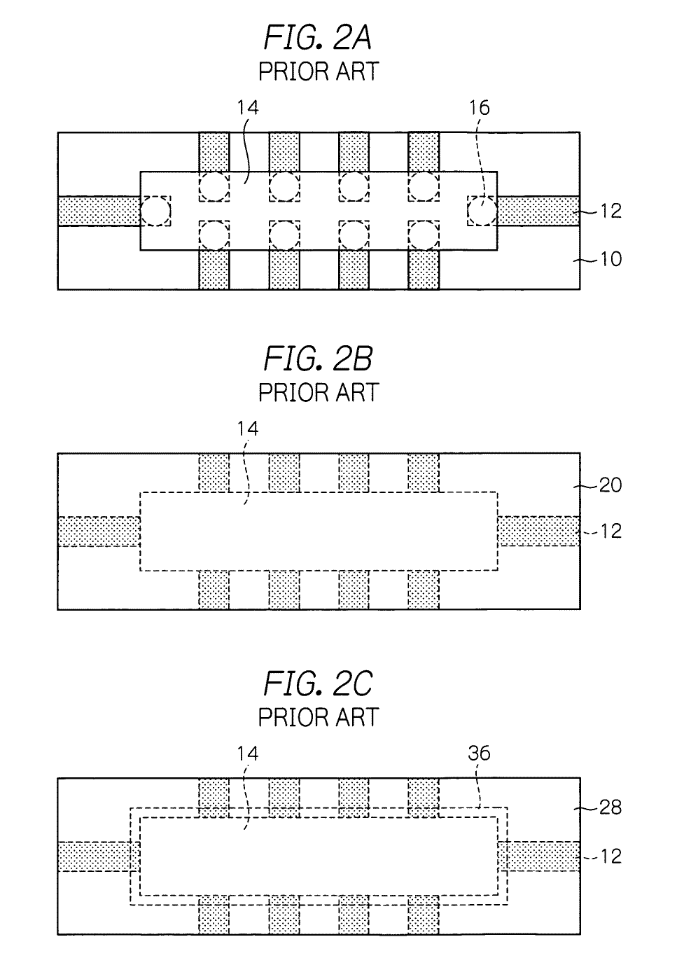

FIGS. 1A to 1C and 2A to 2C are cross sectional and plan views, respectively, useful for understanding the configuration of a conventional module substrate. The module substrate has its structure layered. Thus, in order to expedite understanding a module substrate having a layered structure, the structures of a module substrate are shown in the figures in the time-sequential order of the fabrication at important ones of the initial to final steps of fabricating the module substrate. FIGS. 1A, 1B and 1C are cross sectional views cut along a plane perpendicular to a main surface of a dielectric substrate on which a heat-generative electronic component is mounted. FIGS. 2A, 2B and 2C are plan views as viewed in a direction perpendicular to the main surface of that dielectric substrate shown in FIGS. 1A, 1B and 1C, respectively.

As seen from FIGS. 1A and 2A, in the configuration of a typical conventional module substrate, a heat-generative electronic component 14 is flip-chip bonded through a solder bump 16 on a wiring layer 12 formed on one 34 of primary surfaces of a first dielectric substrate 10.

As seen from FIG. 1C, the heat-generative electronic component 14 has a generally rectangular vertical cross section, and has its lower, in the figure, surface 32 facing the first dielectric substrate 10 and its upper surface 30 opposite to the lower surface 32. Above the upper surface 30, a second dielectric substrate 26 is positioned with an insulating layer 20 intervening. In other words, the configuration of the typical conventional module substrate has the heat-generative electronic component 14 sandwiched between the first and second dielectric substrates 10 and 26 to form a module substrate having a heat-generative electronic component built-in.

That conventional module substrate can be manufactured by a process including steps of mounting the electric component 14 by flip-chip bonding and attaching the second dielectric substrate 26.

In the flip-chip bonding step, the first dielectric substrate 10 having the wiring layer 12 formed on the main surface 34 is prepared, and electrical connection of the heat-generative electronic component 14 to the wiring layer 12 is formed through the solder bump 16.

In an intermediate dielectric substrate attaching step, an intermediate dielectric substrate 24 is prepared which has a hole 36, FIG. 1C, cut therein for surrounding the heat-generative electronic component 14, and is attached by a dielectric adhesive agent to the main surface 34 of the first dielectric substrate 10 and the upper surface 30, opposite to the first dielectric substrate 10, of the heat-generative electronic component 14 so as to fit the heat-generative electronic component 14 into the hole 36. The dielectric adhesive agent is then solidified to complete the insulating layer 20.

On the main surface 34 of the first dielectric substrate 10, the wiring layer 12 is partially formed. Therefore, in such a region of the main surface 34 of the first dielectric substrate 10 where the wiring layer 12 is formed, the intermediate dielectric substrate 24 is attached to the wiring layer 12 formed on the main surface 34 through the dielectric adhesive agent, rather than the main surface 34 of the first dielectric substrate 10.

In the second dielectric substrate attaching step, the second dielectric substrate 26 is arranged in close contact onto an upper surface 38 of the intermediate dielectric substrate 24, which surface will face the second dielectric substrate 26, thereby forming the second dielectric substrate 26 over the entire structure.

In the step shown in FIG. 1B, the dielectric adhesive agent is applied for forming the insulating layer 20 so as to cover the main surface 34 of the first dielectric substrate 10, the wiring layer 12 formed on the main surface 34 and the upper surface 30 of the heat-generative electronic component 14. After having applied, but before solidifying, the dielectric adhesive agent, the intermediate dielectric substrate 24 having the hole 36 formed for surrounding the heat-generative electronic component 14 is placed so that the heat-generative electronic component 14 is fitted into the hole 36 and a lower surface 42 of the intermediate dielectric substrate 24 facing the first dielectric substrate 10 is parallel to the main surface 34 of the first dielectric substrate 10.

Subsequently, the lower surface 44 of the second dielectric substrate 26 adjacent to the heat-generative electronic component 14 is adhered in close contact to the upper surface 38 of the intermediate dielectric substrate 24. Thus, the intermediate dielectric substrate 24 is attached to the first dielectric substrate 10 and in turn the second dielectric substrate 26 is positioned, thereby forming the upper surface 30 of the heat-generative electronic component 14 and the lower surface 44 of the second dielectric substrate 26 in parallel with each other.

The adhesive agent, not shown in the figures, for adhering the lower surface 44 of the second dielectric substrate 26 onto the upper surface 38 of the intermediate dielectric substrate 24 may be the same as or different from that for forming the insulating layer 20.

As shown in FIG. 2A, when the flip-chip bonding step of forming the conventional module substrate is completed, the heat-generative electronic component 14 can directly be viewed. The heat-generative electronic component 14 is electrically connected to the wiring layer 12 formed on the main surface 34 of the first dielectric substrate 10 through the solder bump 16 at a total of ten points, thereby accomplishing the flip-chip bonding. As shown in FIG. 2B, when the step of applying the dielectric adhesive agent for forming the insulating layer 20 so as to cover the wiring layer 12 and the upper surface 30 of the heat-generative electronic component 14 is finished, the wiring layer 12 and the heat-generative electronic component 14 are covered with the dielectric adhesive agent. As shown in FIG. 2C, after having attached the second dielectric substrate 26, a top heat radiation film 28 is formed on the upper surface 40, FIG. 1C, of the second dielectric substrate 26, the upper surface 40 being opposite to one surface 44 of the second dielectric substrate 26 adjacent to the heat-generative electronic component 14.

In contrast to the top heat radiation film 28, a bottom heat radiation film 18 is formed on the other main surface, i.e. bottom surface, 46 opposite to the main surface 34 of the first dielectric substrate 10 adjacent to the heat-generative electronic component 14. Therefore, in the configuration of the conventional module substrate, heat generated by the heat-generative electronic component 14 is eventually radiated through the top and bottom heat radiation films 28 and 18 to the exterior.

Note that the figures do not depict a downward heat radiation mechanism for radiating heat generated by the heat-generative electronic component 14 through the bottom heat radiation film 18 to the exterior, which will be described below.

Usually, a conventional type of module substrate similar to the above has a space between the lower surface 32 of the heat-generative electronic component 14 facing the first dielectric substrate 10 and the main surface 34 of the first dielectric substrate 10 filled with a well-known underfill material 22. The underfill material 22 is electrically insulative and not high in heat conductivity.

In the downward heat radiation mechanism, some measures, such as a via hole for heat radiation, not shown, are often formed to render a heat-generating point of the heat-generative electronic component 14 communicate with the bottom heat radiation film 18. The heat radiation via hole is formed so as to penetrate the first dielectric substrate 10, and composed of a material having high heat conductivity, such as copper.

To a dielectric material for forming the first dielectric substrate 10 and the second dielectric substrate 26, an insulative resin material, such as a Teflon (trademark) or glass epoxy, is applicable. Generally, such a dielectric substrate has its surface, on which the wiring layer 12 composed of an electrically conductive material, such as copper, is deposited to form a circuit pattern. To the dielectric adhesive agent for forming the insulating layer 20, an epoxy resin adhesive may be applied. To the underfill material 22, a thermoset epoxy resin may be applied.

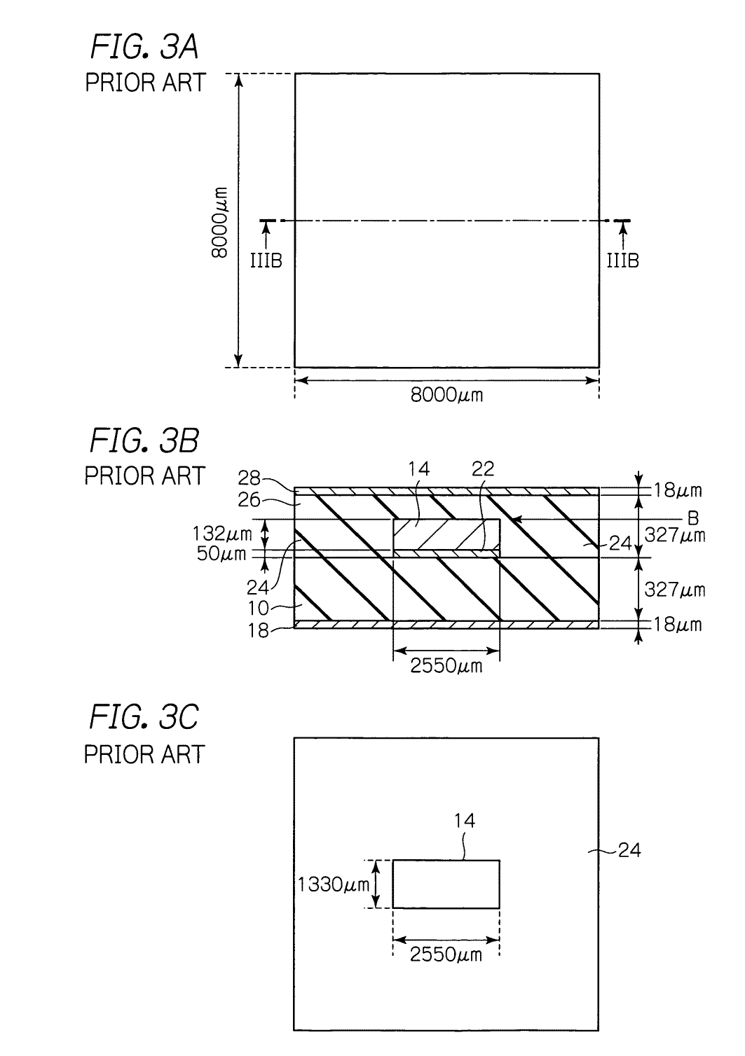

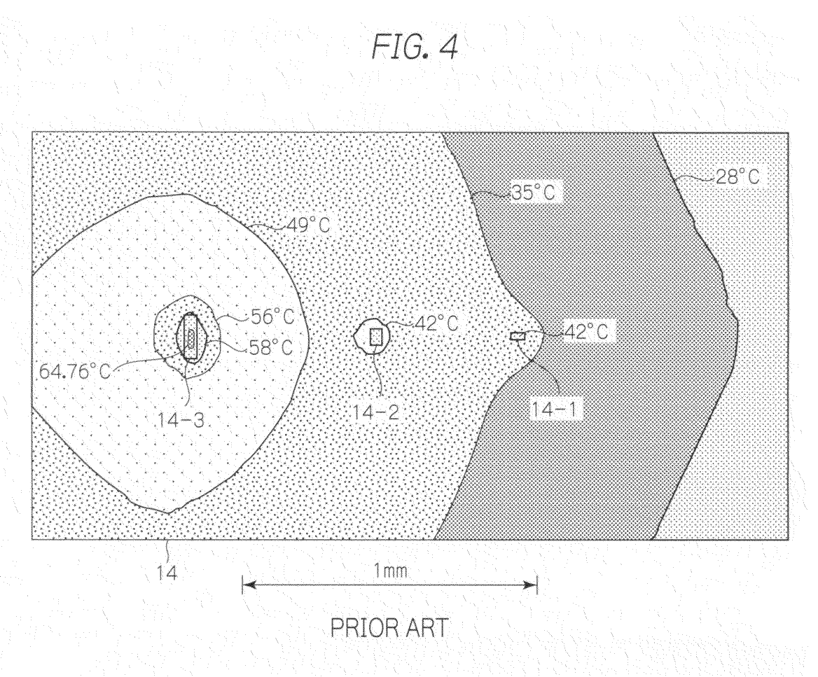

Next, with reference to FIGS. 3A to 3C and 4, described will be a result of simulative estimation on the heat radiation characteristics of the conventional module substrate having the heat-generative electronic component. FIGS. 3A, 3B and 3C will be referred to for describing conditions set for the simulation. FIG. 4 shows a surface temperature distribution obtained from the simulation on the heat-generative electronic component.

FIG. 3A is a top plan view showing a conventional module substrate to be simulated. In this simulation, the module substrate used has a square shape, in a plan view, having its side length equal to 8000 μm, or 8 mm.

FIG. 3B is a cross sectional view showing the conventional module substrate cut along line IIIB-IIIB shown in the top plan view of FIG. 3A.

FIG. 3C is a plan view virtually showing the plane of the conventional module substrate at the level indicated by an arrow B in FIG. 3B, to illustrate the shape and position of the heat-generative electronic component 14, FIG. 3B, which may also correspond to the heat-generative electronic component 14 shown in FIGS. 1A and 2A. The heat-generative electronic component 14 is a rectangular shape, in a plan view, having a length of 1330 μm and a width of 2550 μm, and is positioned in the center of the module substrate.

As shown in FIG. 3B, the lower and top heat radiation films 18 and 28 have a thickness of 18 μm. The heat-generative electronic component 14 and the intermediate dielectric substrate 24 have a thickness of 132 μm, i.e. in height. The underfill material 22 has a thickness of 50 μm and the first dielectric substrate 10 has a thickness of 327 μm, also in height. The second dielectric substrate 26 has predominantly a thickness of 327 μm and partly 195 μm corresponding to 327 μm-132 μm.

The simulation was performed by using the heat-generative electronic component 14 made of base material having its heat conductivity of 68 W/(m·K), and using the first, intermediate and second dielectric substrates 10, 24 and 26 made of dielectric material having its heat conductivity of 0.2 W/(m·K). In the simulation, the heat conductivity of the underfill material 22 was 0.4 W/(m·K), and the heat conductivity of the bottom and top heat radiation films 18 and 28, and the wiring layer 12 was 390 W/(m·K).

In the simulation, the heat-generative electronic component 14 was assumed as an MMIC (microwave monolithic integrated circuit) having three-stage structure. In other words, the MMIC having three-stage structure includes first, second and third stage circuits 14-1, 14-2 and 14-3. The first, second and third stage circuits 14-1, 14-2 and 14-3 are fed with the electric powers of 3 V-30 mA, 3 V-60 mA and 3.2 V-120 mA, respectively.

With reference to FIG. 4, described will be a surface temperature distribution obtained from the simulation on the heat-generative electronic component. The outmost rectangle shown in FIG. 4 represents the outline of the heat-generative electronic component 14, and has a length of 1330 μm and a width of 2550 μm, see FIG. 3C also. In order to facilitate understanding the size of the heat-generative electronic component 14, FIG. 4 also shows a scale indicating the length of 1 mm, or 1000 μm. The temperature distribution shown in FIG. 4 is depicted as measured on the top surface of the top heat radiation film 28.

As shown in FIG. 4, in the three-stage structured MMIC, the ambient temperatures of, i.e. temperatures in the areas surrounding, the first and second stage circuits 14-1 and 14-2 are 42° C. The ambient temperature of the third stage circuit 14-3 is almost 60° C., and the highest temperature of the third stage circuit 14-3 is 64.76° C.

As described above, the conventional module substrate shown in FIGS. 1A to 4 is configured with the heat-generative electronic component 14 surrounded by a material having low heat conductivity. Due to such a configuration, it is difficult to radiate the heat generated by the heat-generative electronic component 14 through the lower and top heat radiation films 18 and 28. As described above, the highest ambient temperature of the third stage circuit 14-3 in the three-stage structured MMIC serving as the heat-generative electronic component 14 is 64.76° C., which is significantly high.

By contrast, in accordance with preferred embodiments of the present invention, a module substrate is particularly characterized by including a mechanism for promoting the radiation of heat through the top heat radiation film 28. Therefore, heat radiated through the bottom heat radiation film 18 to the exterior will not be taken into account.

The module substrates in accordance with preferred embodiments may be similar to the conventional module substrate described above so far as the structure below the heat-generative electronic component 14 to the bottom heat radiation film 18 is concerned. Therefore, discussion on the temperature characteristics of module substrates in accordance with preferred embodiments will be directed to the surface temperature of the top heat radiation film 28 to thereby clarify differences over the conventional module substrate.

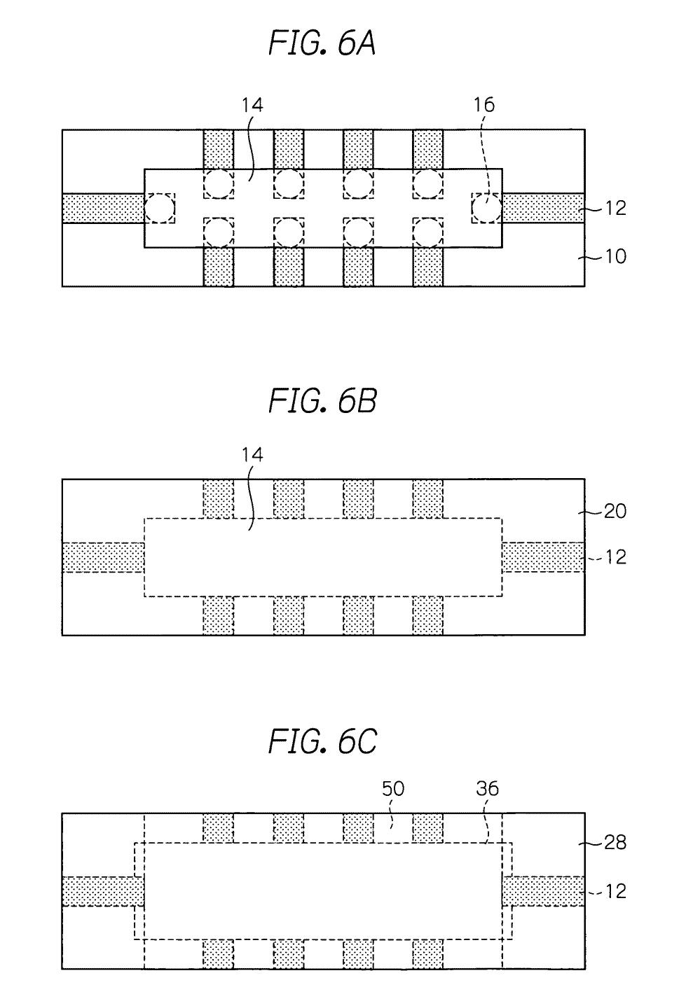

Now, with reference to FIGS. 5A to 5C and 6A to 6C, described will be a microelectronic module assembly, implemented as a module substrate having a heat-generative electronic component, in accordance with a preferred embodiment of the present invention, specifically in terms of its configuration. FIGS. 5A, 5B and 5C are cross sectional views cut along a plane perpendicular to the main surface of a dielectric substrate having a heat-generative electronic component 14 mounted thereon. FIGS. 6A, 6B and 6C are plan views as viewed in a direction perpendicular to the main surface of the dielectric substrate having shown in FIGS. 5A, 5B and 5C, respectively.

The module substrate in accordance with the preferred embodiment is specifically different over the conventional module substrate described above in that the embodiment includes an intermediate heat transfer film 50, FIG. 5C, for transferring heat generated by the heat-generative electronic component 14 to the second dielectric substrate 26. More specifically, as clearly understood from FIG. 5C, the intermediate heat transfer film 50 is disposed between the insulating layer 20 formed on the upper surface 30 of the heat-generative electronic component 14 and the second dielectric substrate 26 in close contact with the lower surface 44 of the second dielectric substrate 26.

The module substrate of the preferred embodiment thus differs from the conventional module substrate particularly in the intermediate heat transfer film 50 additionally provided. The remaining part of the structure may be the same as the conventional module substrate described above. Therefore, repetitive descriptions on like components and elements will be avoided.

The module substrate in accordance with the preferred embodiment may be fabricated by a process including the following steps. Specifically, the module substrate in accordance with the embodiment may be fabricated in the above-described process for manufacturing the conventional module substrate with its step of attaching the second dielectric substrate modified to read below.

With the preferred embodiment, the second dielectric substrate attaching step may be applied in such a fashion that the second dielectric substrate 26 provided with the intermediate heat transfer film 50 is prepared and is then positioned on the upper surface 30 of the heat-generative electronic component 14 through a dielectric adhesive agent, which will be solidified to serve as the insulating layer 20, with its portion 44a not provided with the intermediate heat transfer film 50 on the lower surface 44 being in close contact with the upper surface 38 of the intermediate dielectric substrate 24, thereby attaching the second dielectric substrate 26.

The module substrate of the embodiment may be fabricated in the same process, except for the second dielectric substrate attaching step described above, as the conventional module substrate. Therefore, repetitive descriptions on the remaining part of the process will be refrained from.

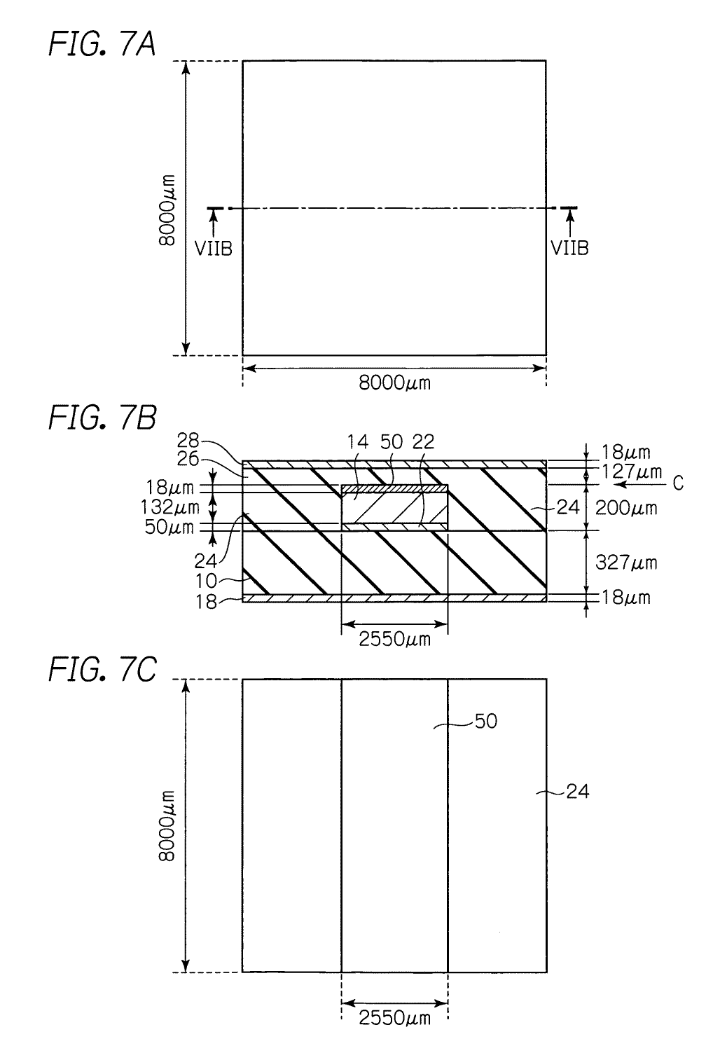

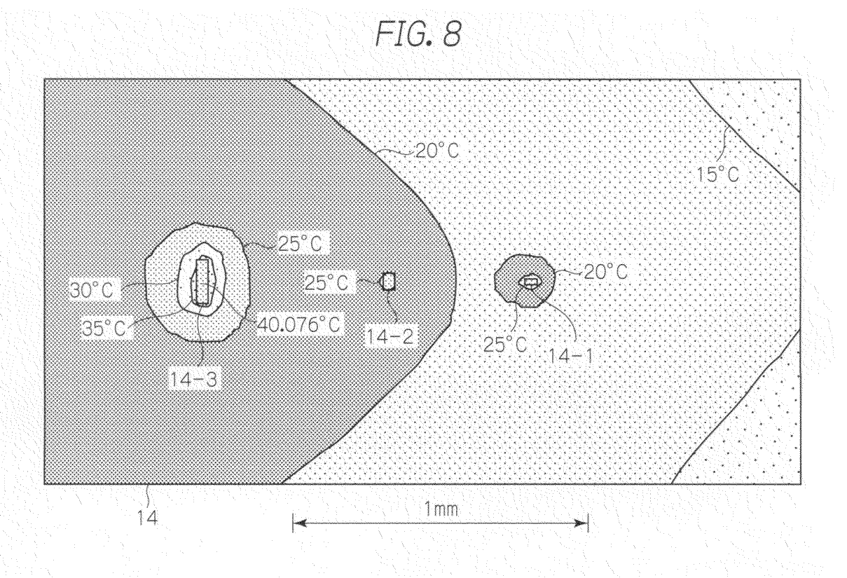

Next, with reference to FIGS. 7A to 7C and 8, described will be a result of a simulative estimation on the heat radiation characteristics of the module substrate having the heat-generative electronic component in accordance with the preferred embodiment. FIGS. 7A, 7B and 7C are for use in understanding conditions set for the simulation. FIG. 8 shows a surface temperature distribution obtained from the simulation on the heat-generative electronic component 14 of the embodiment.

FIG. 7A is a top plan view showing the module substrate to be simulated in accordance with the preferred embodiment. In this simulation also, the module substrate has a square shape, in a plan view, having its side length of 8000 square μm, or 8 square mm.

FIG. 7B is a cross sectional view showing the module substrate of the embodiment cut along line VIIB-VIIB shown in the top plan view of FIG. 7A.

FIG. 7C is a top plan view virtually showing the plane of the module substrate of the embodiment at the level indicated by an arrow C in FIG. 7B, to illustrate the shape and position of the intermediate heat transfer film 50. The intermediate heat transfer film 50 is a rectangular shape, in a plan view, having a width of 2550 μm and a length of 8000 μm substantially equal to the length of the side of the module substrate 14.

The shape of the intermediate heat transfer film 50 is not necessarily congruous with the upper surface 30 of the heat-generative electronic component 14. It may be sufficient that at least a part of the intermediate heat transfer film lies immediately on the upper surface 30 of the heat-generative electronic component 14, for example, and therefore the intermediate heat transfer film 50 may extend substantially broader than the upper surface 30 of the heat-generative electronic component 14. Rather, so far as the electric operating characteristics of the heat-generative electronic component 14 is not affected, it is effective to form the intermediate heat transfer film 50 as broad in area as possible from the viewpoint of improving heat radiation.

As shown in FIG. 7B, the lower and top heat radiation films 18 and 28 have a thickness of 18 μm. The heat-generative electronic component 14 and the intermediate dielectric substrate 24 have a thickness of 132 μm, and the underfill material 22 has a thickness of 50 μm. The first dielectric substrate 10 has a thickness of 327 μm, the second dielectric substrate 26 has a thickness of 127 μm and the intermediate heat transfer film 50 has a thickness of 18 μm.

The simulation was performed by using the heat-generative electronic component 14 made of base material having its heat conductivity of 68 W/(m·K), and using the first, intermediate and second dielectric substrates 10, 24 and 26 made of dielectric material having its heat conductivity of 0.2 W/(m·K). In the simulation, the heat conductivity of the underfill material 22 was 0.4 W/(m·K), and the heat conductivity of the lower and top heat radiation films 18 and 28, and the wiring layer 12 was 390 W/(m·K).

In the simulation, the heat-generative electronic component 14 of the preferred embodiment was assumed as an MMIC having three-stage structure, similarly to the simulation described above in respect of the conventional module substrate.

With reference to FIG. 8, described will be the surface temperature distribution obtained from the simulation on the heat-generative electronic component 14. The outmost rectangle shown in FIG. 8 represents the shape of the heat-generative electronic component 14 shown in FIG. 7C, and has its width of 2550 μm. FIG. 8 show the temperature distribution observed over the upper surface of the top heat radiation film 28 corresponding to the electronic component 14.

As seen from FIG. 8, in the three-stage structured MMIC of the preferred embodiment, the ambient temperatures of the first and second stage circuits 14-1 and 14-2 are 25° C. The ambient temperature of the third stage circuit 14-3 is almost 40° C., and the highest temperature of the third stage circuit 14-3 is 40.076° C. Thus, the highest temperature of the third stage circuit 14-3 of the preferred embodiment is lower than the highest temperature of 64.67° C. in the above-described conventional module substrate by no less than 24.594° C. Therefore, according to the module substrate in accordance with the preferred embodiment, it was confirmed that the temperature of the heat-generative electronic component in operation could more effectively be suppressed from increasing that the conventional module substrate.

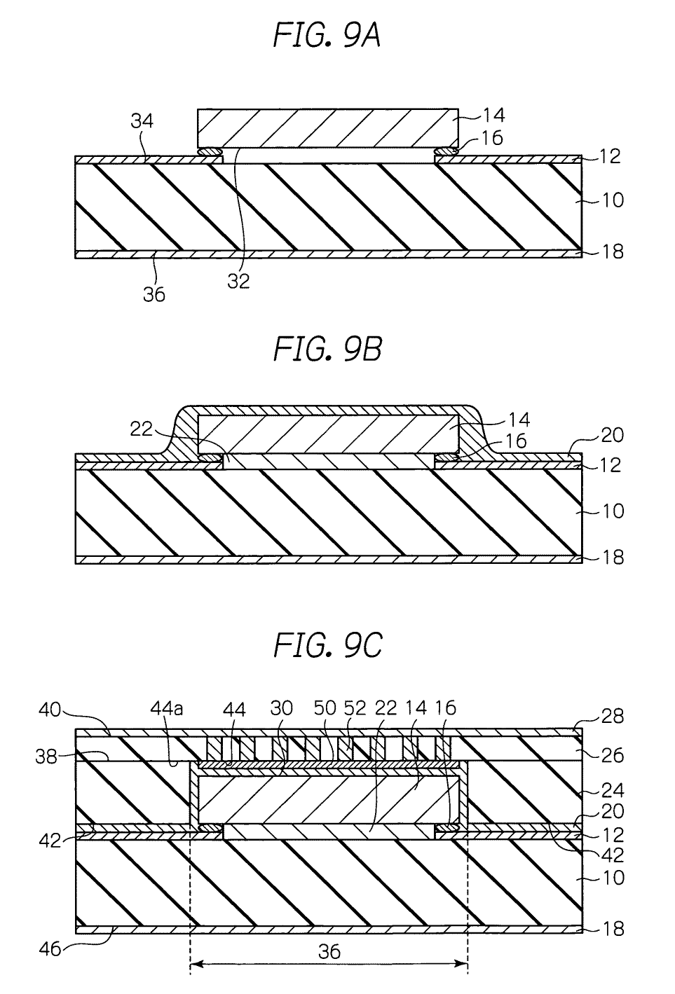

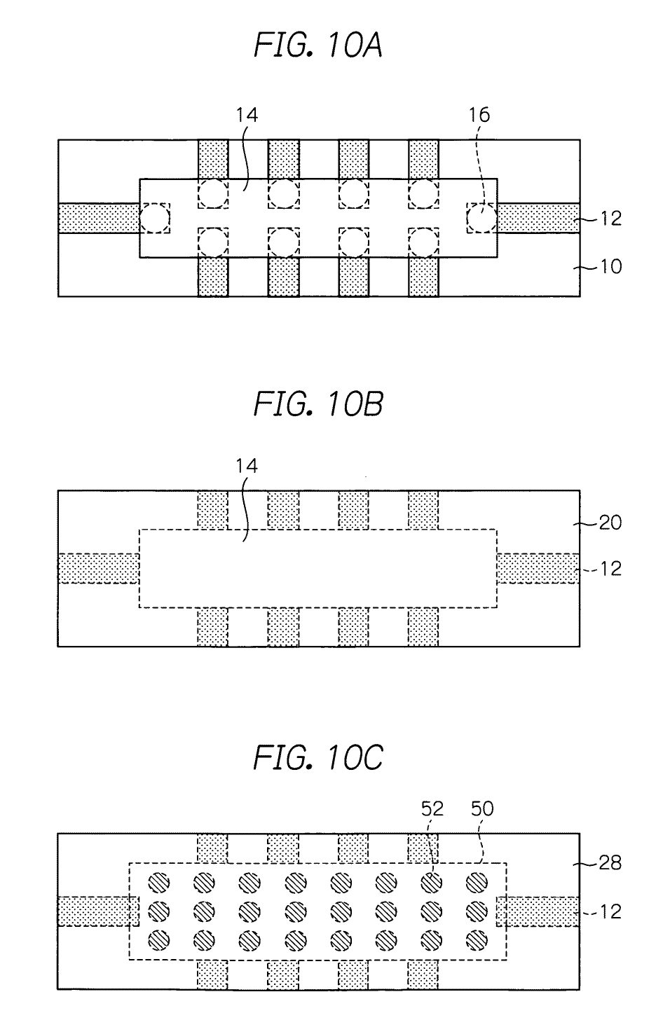

Now, with reference to FIGS. 9A to 9C and 10A to 10C, described will be a module substrate having a heat-generative electronic component in accordance with an alternative embodiment of the present invention. FIGS. 9A, 9B and 9C are cross sectional views cut along a plane perpendicular to the main surface of a dielectric substrate having a heat-generative electronic component 14 mounted thereon. FIGS. 10A, 10B and 10C are plan views as viewed in a direction perpendicular to the main surface of the dielectric substrate shown in FIGS. 9A, 9B and 9C, respectively.

The module substrate in accordance with the alternative embodiment may be the same as the preferred embodiment show in and described with reference to FIGS. 5A to 6C except for the top heat radiation film 28 having through holes 52 cut therethrough to connect its lower surface 44 to its upper surface 40, opposite to the former, to form a structure for conducting the heat from the intermediate heat transfer film 50 to the top heat radiation film 28. The through holes 52 may be filled with filler material thermally conductive.

More specifically, the module substrate of the alternative embodiment is differed from the module substrate shown in and described with reference to FIGS. 5A to 6C in the through holes 52 newly provided to connect the intermediate heat transfer film 50 and the top heat radiation film 28 to each other and in the size of the intermediate heat transfer film 50. In other part configuration, the alternative embodiment may be the same as the module substrate shown in FIGS. 5A to 6C. Therefore, repetitive descriptions on like components and elements will be avoided.

The module substrate in accordance with the alternative embodiment may be fabricated by a process for manufacturing the module substrate including the following steps.

The process for manufacturing the module substrate of the alternative embodiment includes, in addition to the flip-chip bonding, intermediate dielectric substrate attaching and second dielectric substrate attaching steps described above, a through hole forming step and a top heat radiation film forming step following the second dielectric substrate attaching step.

In the through hole forming step, the through holes 52 are formed in the second dielectric substrate 26. In the top heat radiation film forming step, the top heat radiation film 28 is formed on the upper surface 40, opposite to the heat-generative electronic component 14, of the second dielectric substrate 26 thus provided with the through holes 52. The through hole forming step may be performed by a conventional technique disclosed by, for example, Japanese patent laid-open publication Nos. 2001-332650 and 2008-251935. Further details thereon will therefore not be described.

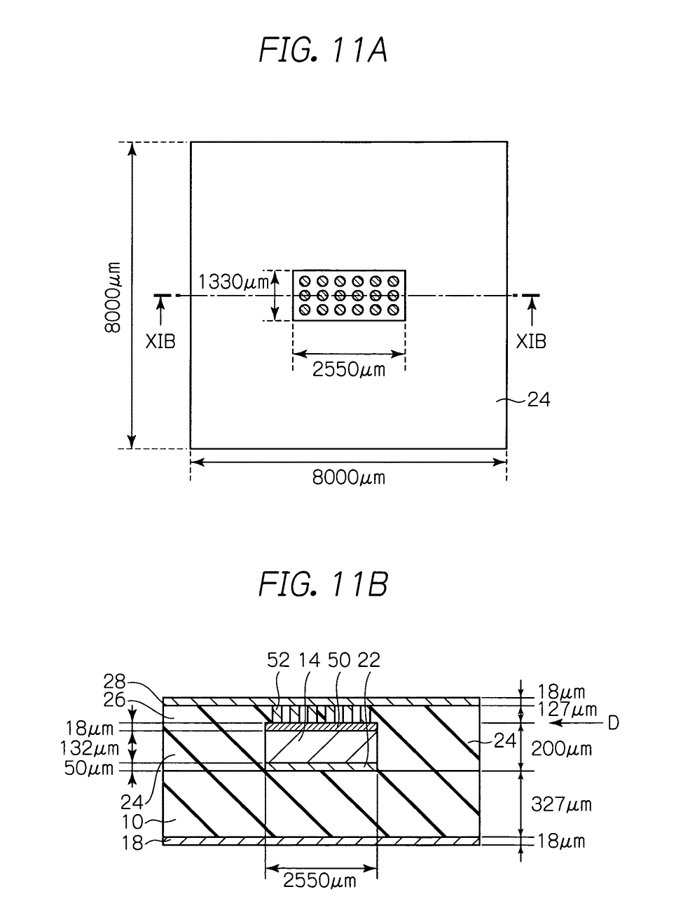

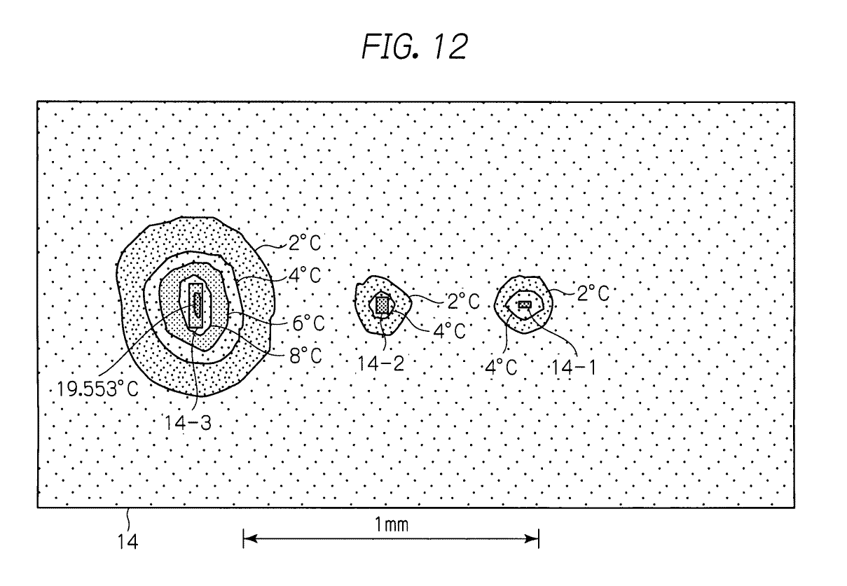

Next, with reference to FIGS. 11A, 11B and 12, described will be a result of simulative estimation of heat radiation characteristics of the module substrate having the heat-generative electronic component in accordance with the alternative embodiment. FIGS. 11A and 11B are virtual plan and cross sectional views, respectively, useful for understanding conditions set for the simulation. FIG. 12 shows a surface temperature distribution obtained from the simulation on the heat-generative electronic component of the alternative embodiment.

FIG. 11A virtually shows in a plan view the module substrate 14 to be simulated in accordance with the alternative embodiment with the top heat radiation film 28 removed simply for illustration, or cut at an arrow D in FIG. 11B. In this simulation also, the module substrate 14 has a square shape, in a plan view, having its side length of 8000 μm, or 8 mm. As shown in the figure, the through holes 52 are positioned within a region corresponding to the upper surface of the heat-generative electronic component 14, the upper surface having its length of 1330 μm and its width of 2550 μm.

FIG. 11B is a cross sectional view showing the module substrate cut along line XIB-XIB in the virtual plan view shown in FIG. 11A. From the figure, it can be seen how the top heat radiation film 28 is connected with the intermediate heat transfer film 50 by the through holes 52.

As depicted in FIG. 11B, the bottom heat radiation film 18 and the top heat radiation film 28 have a thickness of 18 μm. The heat-generative electronic component 14 and the intermediate dielectric substrate 24 have a thickness of 132 μm and the underfill material 22 has a thickness of 50 μm. The first dielectric substrate 10 has a thickness of 327 μm, the second dielectric substrate 26 has a thickness of 127 μm and the intermediate heat transfer film 50 has a thickness of 18 μm.

The simulation was performed by using the heat-generative electronic component 14 made of base material having its heat conductivity of 68 W/(m·K), and using the first, intermediate and second dielectric substrates 10, 24 and 26 made of dielectric material having its heat conductivity of 0.2 W/(m·K). In the simulation, the heat conductivity of the underfill material 22 was 0.4 WI (m·K), and the heat conductivity of the lower and top heat radiation films 18 and 28, and the wiring layer 12 was 390 W/(m·K).

In the simulation also, the heat-generative electronic component 14 of the alternative embodiment was assumed as an MMIC having three-stage structure, similarly to the simulation described above in respect of the conventional module substrate.

In the simulation conducted as shown in FIGS. 11A and 11B, conditions set therefor may be the same as the simulation described with reference to FIGS. 7A and 7B except for the conditions described above as well as the through holes 52 provided and the area of the intermediate heat transfer film 50.

With reference to FIG. 12, description will be made on the surface temperature distribution of the heat-generative electronic component 14 obtained from the simulation. The outmost rectangle shown in FIG. 12 represents the shape of the heat-generative electronic component 14, and has its length of 1330 μm and its width of 2550 μm. FIG. 12 shows the temperature distribution of the upper surface of the top heat radiation film 28.

As understood from FIG. 12, in the three-stage structured MMIC of the alternative embodiment, the ambient temperatures of the first and second stage circuits 14-1 and 14-2 are 4° C. The ambient temperature of the third stage circuit 14-3 is approximately 19° C., and the highest temperature of the third stage circuit 14-3 is 19.553° C. Thus, the highest temperature of the third stage circuit 14-3 of the alternative embodiment is lower than the highest temperature of 40.076° C. in the module substrate of the illustrative embodiment shown in and described earlier with reference to FIGS. 5A to 6C by no less than 20.523° C. Therefore, with the module substrate in accordance with the alternative embodiment, it was confirmed that the temperature of the heat-generative electronic component in operation could further effectively be controlled than the module substrate of the embodiment described earlier.

As discussed earlier, the illustrative embodiment shown in and described with reference to FIGS. 5A to 6C is more effectively applicable to an application where the intermediate heat transfer film 50 is allowed less limitative in designing to its dimension so as to be attached to the heat-generative electronic component 14 having its upper surface 30 different in shape therefrom. Therefore, the intermediate heat transfer film 50, when designed larger in dimension than the surface of the electronic component 14, can improve the heat radiation efficiency without requiring a manufacturing step for forming through holes, thereby reducing the cost in manufacturing.

The module substrate in accordance with the alternative embodiment is more effective in a case where it is difficult to increase, or forced to render comparable, the area of the intermediate heat transfer film 50, for example, where the electric operating characteristics of the heat-generative electronic component 14 is sensitively affected by the intermediate heat transfer film 50. Therefore, even when it is difficult to increase the dimension of the intermediate heat transfer film 50, the through holes 52 can radiate the heat sufficiently efficiently.

The entire disclosure of Japanese patent application No. 2009-223783 filed on Sep. 29, 2009, including the specification, claims, accompanying drawings and abstract of the disclosure, is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What I claim is:

1. A microelectronic module assembly comprising:
a first dielectric substrate having a main surface on which a wiring layer is formed;
a heat-generative electronic component flip-chip bonded on said wiring layer through a solder bump;
a second dielectric substrate attached through an insulating layer to a first surface, opposite to a second surface facing said first dielectric substrate, of said heat-generative electronic component to thereby arrange said heat-generative electronic component between said first and second dielectric substrates; and
an intermediate heat transfer film arranged between said insulating layer and said second dielectric substrate in a close contact with a first surface of said second dielectric substrate adjacent to said heat-generative electronic component for transferring heat generated by said heat-generative electronic component to said second dielectric substrate.

2. The assembly in accordance with claim 1, further comprising a top heat radiation film formed on a second surface opposite to the first surface of said second dielectric substrate,
said intermediate heat transfer film and said top heat radiation film being connected with each other by a through hole.

3. The assembly in accordance with claim 1, wherein said assembly is a module substrate having the heat-generative electronic component mounted thereon.

4. The assembly in accordance with claim 1, wherein said intermediate heat transfer film is formed substantially broader than the first surface of said heat-generative electronic component.

5. The assembly in accordance with claim 1, wherein said intermediate heat transfer film is formed substantially same in area as the first surface of said heat-generative electronic component.

6. A method for manufacturing a microelectronic module assembly, comprising:
a flip-chip bonding step of preparing a first dielectric substrate having a main surface on which a wiring layer is formed, and forming an electrical connection of a heat-generative electronic component to the wiring layer through a solder bump;
an intermediate dielectric substrate attaching step of preparing an intermediate dielectric substrate having a hole formed for surrounding the heat-generative electronic component, applying a dielectric adhesive agent to the main surface and a first surface of the heat-generative electronic component, and attaching the intermediate dielectric substrate to the main surface by the dielectric adhesive agent so as to fit the heat-generative electronic component into the hole; and
a second dielectric substrate attaching step of preparing a second dielectric substrate having a first surface provided with an intermediate heat transfer film, and attaching the second dielectric substrate so as to position the intermediate heat transfer film through the dielectric adhesive agent above the first surface of the heat-generative electronic component and so as to bring a portion of the second dielectric substrate not provided with the intermediate heat transfer film into close contact with a surface, opposite to the main surface, of the intermediate dielectric substrate.

7. The method in accordance with claim 6, further comprising, subsequent to said second dielectric substrate attaching step:
a through hole forming step of forming a through hole in the second dielectric substrate; and
a top heat radiation film forming step of forming a top heat radiation film on a second surface opposite to the first surface of said second dielectric substrate.
